(19) United States
(12) Patent Application Publication
(10) Pub. No.: US 2016/0293816 A1
(43) Pub. Date: Oct. 6, 2016

(54) SEMICONDUCTOR DEVICE, SEMICONDUCTOR DEVICE ARRAY, AND IMAGE FORMATION APPARATUS

(71) Applicant: Oki Data Corporation, Tokyo (JP)

(72) Inventor: Taishi KANETO, Tokyo (JP)

(73) Assignee: Oki Data Corporation, Tokyo (JP)

(21) Appl. No.: 15/065,948

(22) Filed: Mar. 10, 2016

(30) Foreign Application Priority Data
Mar. 31, 2015 (JP) 2015-072288

(51) Int. Cl. H01L 33/62; H01L 25/065; H01L 23/498; G03F 7/20; H01L 25/04; H01L 31/02; H01L 29/167; H01L 23/00; H01L 25/075

(52) U.S. Cl. CPC H01L 33/62; H01L 24/48; H01L 25/0655; H01L 23/49838; H01L 23/49894; H01L 25/0753; H01L 25/042; H01L 31/02002; H01L 29/167; G03F 7/20; H01L 2224/48105; H01L 2224/48137; H01L 2224/48227; H01L 2924/0665; H01L 2924/0635; H01L 2924/066; H01L 2924/07025; H01L 2224/48464; H01L 2224/48465; H01L 2924/0675; H01L 2924/15791; H01L 2924/12041; H01L 2924/12043

(57) ABSTRACT

A semiconductor device includes a first semiconductor chip including a first upper surface and a first electrode pad provided on the first upper surface; a circuit component including a second upper surface disposed at a position lower than the first upper surface and a second electrode pad provided on the second upper surface, the circuit component being juxtaposed to the first semiconductor chip; an insulation member provided on the first upper surface and located closer to the second electrode pad than the first electrode pad is; and a wire extending from the first electrode pad to the second electrode pad and passing above the insulation member.

### CROSS REFERENCE TO RELATED APPLICATIONS

This application claims priority based on 35 USC 119 from prior Japanese Patent Application No. 2015-072288 filed on Mar. 31, 2015, entitled “SEMICONDUCTOR DEVICE, SEMICONDUCTOR DEVICE ARRAY, AND IMAGE FORMATION APPARATUS”, the entire contents of which are incorporated herein by reference.

### BACKGROUND OF THE INVENTION

1. Field of the Invention

This disclosure relates to a semiconductor device, a semiconductor device array such as a light-emitting element array, and an image formation apparatus.

2. Description of Related Art

A conventional method of manufacturing a semiconductor device involves a process of bonding first electrode pads of a first semiconductor chip to second electrode pads of a second semiconductor chip by using wires, while the first semiconductor chip and the second semiconductor chip are disposed on a mount board, then to house the wire-bonded first and second semiconductor chips into a package. The semiconductor chips and the wires are then sealed by filling the package with a resin. However, as a consequence of the filling with the resin, there may be a case in which any of the wires is deformed (in other words, a wire displacement occurs), and the deformed wire may come into contact with a corner portion (an edge) or the like of the first or second semiconductor chip, thereby leading to a short circuit.

FIGS. 13A and 13B are schematic cross-sectional views illustrating a conventional semiconductor device. A conceivable countermeasure is illustrated in FIG. 13A in which a height H1 from an upper surface of first semiconductor chip 2 to an apex of wire 7 is increased in order to reduce the chance of an occurrence of a short circuit between wire 7 and first semiconductor chip 2. However, the increase in the height H1 of wire 7 is likely to increase the chance of an occurrence of a short circuit between adjacent wires. On the other hand, when a height H2 of the apex of wire 7 is reduced as illustrated in FIG. 13B in order to reduce the chance of an occurrence of a short circuit between the adjacent wires, a distance H3 between wire 7 and a corner portion (an edge) of an upper surface of second semiconductor chip 3 becomes smaller. This leads to an increase in the chance of an occurrence of a short circuit between wire 7 and the corner portion (the edge) of second semiconductor chip 3.

In order to reduce the chance of a short circuit between the wire and the corner portion of the second semiconductor chip, there is a proposal in which the second semiconductor chip provided with the second electrode pads to be stitch-bonded to the wires is formed thinner than the first semiconductor chip provided with the first electrode pads to be ball-bonded to the wires (see Japanese Patent Application Publication No. 2004-356382, for example). FIGS. 14A and 14B are schematic cross-sectional views illustrating another conventional semiconductor device. However, when an interval S1 between the first and second semiconductor chips illustrated in FIG. 14A is reduced to an interval S2 as illustrated in FIG. 14B to reduce the size of the semiconductor device, the distance between a corner portion of first semiconductor chip 2a and wire 7a is reduced from a distance D1 in FIG. 14A to a distance D2 in FIG. 14B. As a consequence, there is a problem in that a short circuit is likely to occur between wire 7a and the corner portion of first semiconductor chip 2a.

### SUMMARY OF THE INVENTION

As described above, the conventional semiconductor devices have the problem in that a short circuit between the adjacent wires is likely to occur as a consequence of increasing the height of the wires connecting the first semiconductor chip to the second semiconductor chip. A short circuit is also likely to occur between any of the wires and the corresponding corner portion of the first or second semiconductor chip as a consequence of reducing the height of the wires.

An object of an embodiment of the invention is to provide a semiconductor device, a semiconductor device array, and an image formation apparatus, which can reduce the chance of the occurrence of a short circuit between adjacent wires or between a semiconductor chip and a wire.

An aspect of the invention is a semiconductor device that includes a first semiconductor chip including a first upper surface and a first electrode pad provided on the first upper surface; a circuit component including a second upper surface disposed at a position lower than the first upper surface and a second electrode pad provided on the second upper surface, the circuit component being juxtaposed to the first semiconductor chip; an insulation member provided on the first upper surface and located closer to the second electrode pad than the first electrode pad is; and a wire extending from the first electrode pad to the second electrode pad while passing above the insulation member.

According to this aspect of the invention, the insulation member, which is provided on the upper surface of the first semiconductor chip and is located at a position closer to the end portion than the first electrode pad is, can prevent the occurrence of a short circuit between the corner portion of the first semiconductor chip and the wire even when the wire has a small height from the upper surface of the first semiconductor chip.

Moreover, according to this aspect of the invention, the upper surface of the second semiconductor chip is located lower than the upper surface of the first semiconductor chip. As a consequence, it is possible to reduce the chance of the occurrence of a short circuit between the second semiconductor chip and the wire even when the wire has a small height from the upper surface of the first semiconductor chip.

Furthermore, according to this aspect of the invention, the height of the wire from the upper surface of the first semiconductor chip can be reduced. Thus, it is possible to reduce the chance of the occurrence of a short circuit between adjacent wires.

### BRIEF DESCRIPTION OF THE DRAWINGS

FIG. 1A is a cross-sectional view schematically illustrating a configuration of a semiconductor device according to a first embodiment of the invention, and FIG. 1B is an enlarged cross-sectional view illustrating a substantial part of the semiconductor device in FIG. 1A.

FIG. 2 is a cross-sectional view schematically illustrating the configuration of the semiconductor device according to the first embodiment.

FIGS. 3A to 3C are cross-sectional views illustrating manufacturing steps of a first semiconductor chip in the semiconductor device according to the first embodiment.

FIG. 4A is a cross-sectional view schematically illustrating a configuration of a semiconductor device according to a first modified example of the first embodiment, and FIG. 4B is an enlarged cross-sectional view illustrating a substantial part of the semiconductor device in FIG. 4A.

FIG. 5A is a cross-sectional view schematically illustrating a configuration of a semiconductor device according to a second modified example of the first embodiment, and FIG. 5B is an enlarged cross-sectional view illustrating a substantial part of the semiconductor device in FIG. 5A.

FIGS. 6A to 6F are cross-sectional views illustrating manufacturing steps of a first semiconductor chip in the semiconductor device according to the second modified example of the first embodiment.

FIG. 7A is a cross-sectional view schematically illustrating a configuration of a semiconductor device according to a second embodiment of the invention, and FIG. 7B is an enlarged cross-sectional view illustrating a substantial part of the semiconductor device in FIG. 7A.

FIG. 8A is a cross-sectional view schematically illustrating a configuration of a semiconductor device according to a first modified example of the second embodiment, and FIG. 8B is an enlarged cross-sectional view illustrating a substantial part of the semiconductor device in FIG. 8A.

FIG. 9A is a cross-sectional view schematically illustrating a configuration of a semiconductor device according to a second modified example of the second embodiment, and FIG. 9B is an enlarged cross-sectional view illustrating a substantial part of the semiconductor device in FIG. 9A.

FIG. 10A is a perspective view schematically illustrating a configuration of an optical print head according to a third embodiment of the invention, and FIG. 10B is an enlarged perspective view illustrating a substantial part of the optical print head in FIG. 10A.

FIG. 11 is an enlarged perspective view illustrating a main part of the optical print head in FIG. 10B.

FIG. 12 is a vertical cross-sectional view schematically illustrating a configuration of an image formation apparatus according to a fourth embodiment of the invention.

FIGS. 13A and 13B are schematic cross-sectional views illustrating a configuration of a conventional semiconductor device.

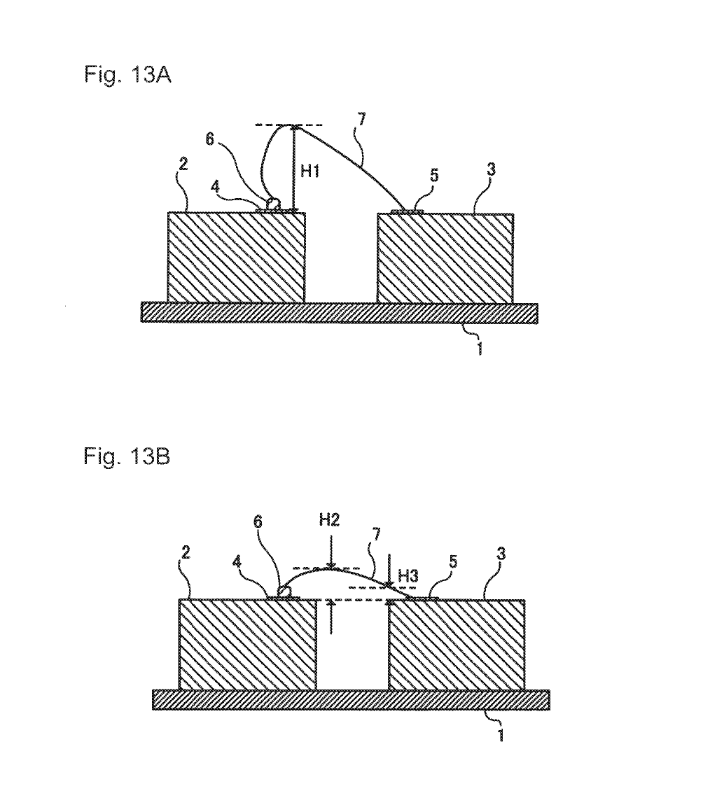

FIGS. 14A and 14B are schematic cross-sectional views illustrating a configuration of another conventional semiconductor device.

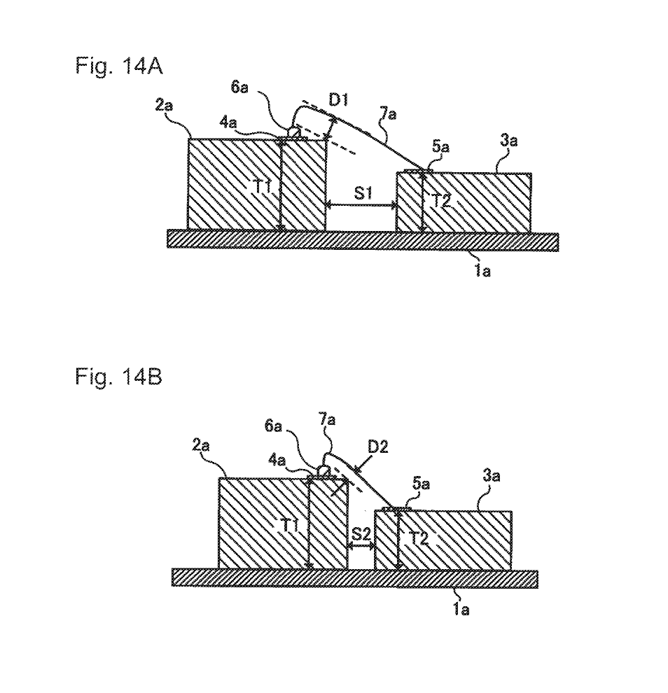

### DETAILED DESCRIPTION OF EMBODIMENTS

Descriptions are provided hereinbelow for embodiments based on the drawings. In the respective drawings referenced herein, the same constituents are designated by the same reference numerals and duplicate explanation concerning the same constituents is omitted. All of the drawings are provided to illustrate the respective examples only.

### First Embodiment

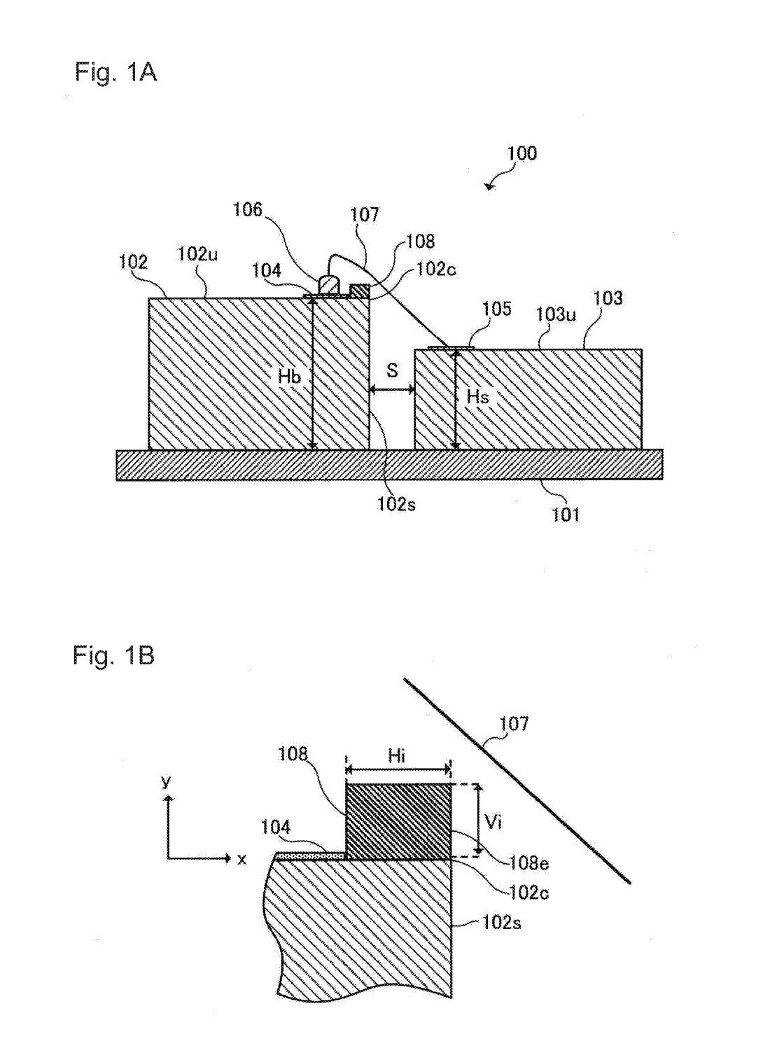

FIG. 1A is a cross-sectional view schematically illustrating a configuration of a semiconductor device according to a first embodiment of the invention, and FIG. 1B is an enlarged cross-sectional view illustrating a substantial part of the semiconductor device in FIG. 1A. As illustrated in FIGS. 1A and 1B, semiconductor device 100 according to the first embodiment includes first semiconductor chip 102, second semiconductor chip 103 serving as a circuit component, insulation member 108, and wire 107. First semiconductor chip 102 and second semiconductor chip 103 are fixed onto mount board 101.

First semiconductor chip 102 may include a light-emitting element or a light-receiving element, for example. First semiconductor chip 102 includes first upper surface 102u and first electrode pad 104 provided on the first upper surface 102u.

Second semiconductor chip 103 may incorporate an integrated circuit or mount an integrated circuit chip, for example. Based on upper surface 102u of first semiconductor chip 102, second semiconductor chip 103 includes second upper surface 103u located at a position lower than first upper surface 102u of first semiconductor chip 102, and second electrode pad 105 provided on second upper surface 103u. In other words, a height Hs of second semiconductor chip 103 from mount board 101 to second electrode pad 105 is smaller than a height Hb of first semiconductor chip 102 from mount board 101 to first electrode pad 104. Second semiconductor chip 103 is disposed on mount board 101 and juxtaposed to first semiconductor chip 102 while defining an interval S in-between.

Each of first semiconductor chip 102 and second semiconductor chip 103 is manufactured, for example, by forming patterns of the semiconductor chips on a semiconductor substrate made of a single-crystal Si or a compound semiconductor such as GaAs, and then splitting the semiconductor substrate provided with such semiconductor structures into pieces. However, the method of manufacturing first semiconductor chip 102 and second semiconductor chip 103 is not limited to the foregoing. Meanwhile, the semiconductor substrate having an electric conductivity is often exposed on side surfaces of first semiconductor chip 102 and second semiconductor chip 103 (i.e., surfaces that connect back surfaces being surfaces on the mount board to upper surfaces located on the opposite side therefrom). However, part or all of the side surfaces of first semiconductor chip 102 and second semiconductor chip 103 may be covered with an insulative substance.

In the first embodiment, the interval S between first semiconductor chip 102 and second semiconductor chip 103 is about 10 μm, for example. The height Hb of first semiconductor chip 102 and the height Hs of second semiconductor chip 103 are several hundreds of micrometers each. The difference between the height Hb and the height Hs is in the range of from several tens of micrometers to several hundreds of micrometers, for example. The distance between the center of first electrode pad 104 and the center of second electrode pad 105 is in the range of from several hundreds of micrometers to several millimeters, for example.

Insulation member 108 is provided on first upper surface 102u of first semiconductor chip 102 and is located closer to second electrode pad 105 than first electrode pad 104 is. Insulation member 108 on first upper surface 102u of first semiconductor chip 102 has a protruding structure made of an insulative material and is located between first electrode pad 104 and corner portion 102c on the second semiconductor chip 103 side. In the first embodiment, end portion 108e of insulation member 108 on the second semiconductor chip 103 side is disposed in such a way as to overlap corner portion 102c as an end portion of upper surface 102u of first semiconductor chip 102 on the second semiconductor chip 103 side. Here, in FIG. 1B, an x-axis direction indicates a direction parallel to an extending direction of first upper surface 102u of first semiconductor chip 102, while a y-axis direction indicates a direction that is perpendicular to the x-axis direction and is also parallel to an extending direction of side surface 102s of first semiconductor chip 102. In the first embodiment, the end portions of insulation member 108 and first semiconductor chip 102 on the second semiconductor chip 103 side are arranged to coincide with each other in the x-axis direction. In other words, end portion 108e of insulation member 108 on the second semiconductor chip 103 side, and corner portion 102c as the end portion of upper surface 102u of first semiconductor chip 102 on the second semiconductor chip 103 side, are disposed in alignment with each other at the same position in the x-axis direction.

The material of insulation member 108 may be any of epoxy resin, polyimide, acrylic resin, phenol resin, and the like. However, the material is not limited to these substances in the invention. Incidentally, as illustrated in FIG. 1B, the height Vi of insulation member 108 is in the range of from several micrometers to several tens of micrometers, while a width Hi thereof is also in the range of from several micrometers to several tens of micrometers, for example.

Wire 107 is a bonding wire disposed in a loop shape to extend from first electrode pad 104 of first semiconductor chip 102 to second electrode pad 105 of second semiconductor chip 103 while passing above insulation member 108. Preferably, wire 107 is ball-bonded (fixed) to first electrode pad 104 and is stitch-bonded (fixed) to second electrode pad 105. In this way, first semiconductor chip 102 is electrically connected to second semiconductor chip 103. The material of wire 107 is any of Au, Al, Cu, alloys thereof, and the like.

Each of a height and a width of ball bond 106 is several tens of micrometers. In the meantime, the distance between ball bond 106 on first electrode pad 104 and side surface 102s of first semiconductor chip 102 is greater than several tens of micrometers. The height from upper surface 102u of first semiconductor chip 102 to an apex of the loop of wire 107 is about 100 μm, for example.

A rigid board, such as a glass epoxy board or a ceramic board, is used as mount board 101. However, mount board 101 is not limited to these boards. Alternatively, mount board 101 may be a flexible board that uses a polyimide film, a polyester film, and the like as the material. Mount board 101 may be a printed wiring board of any of the following types: a single-sided board provided with a wiring layer on one surface of the board, a double-sided board provided with wiring layers on two surfaces of the board, and a multi-layered substrate provided with wiring layers on one or more surfaces as well as top and bottom surfaces of the board.

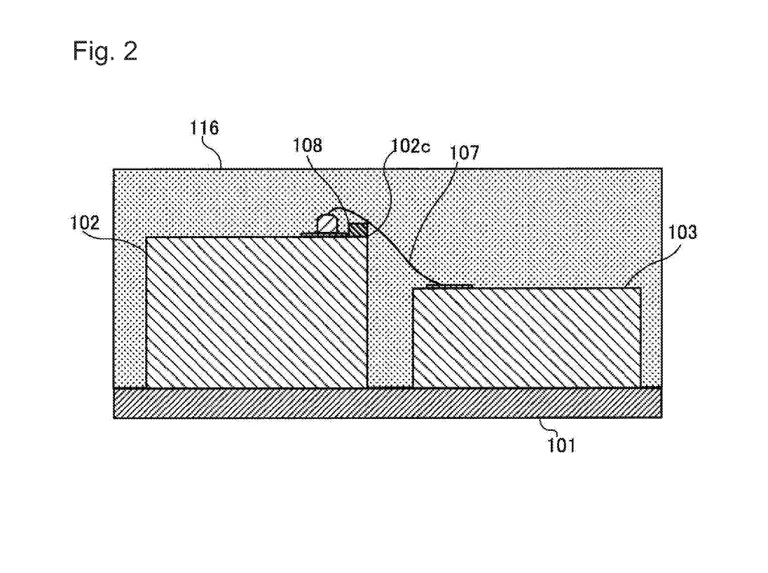

FIG. 2 is a cross-sectional view schematically illustrating a configuration of semiconductor device 100 according to the first embodiment. FIG. 2 illustrates a state of semiconductor device 100 when a package mounting semiconductor device 100 according to the first embodiment is sealed with resin 116.

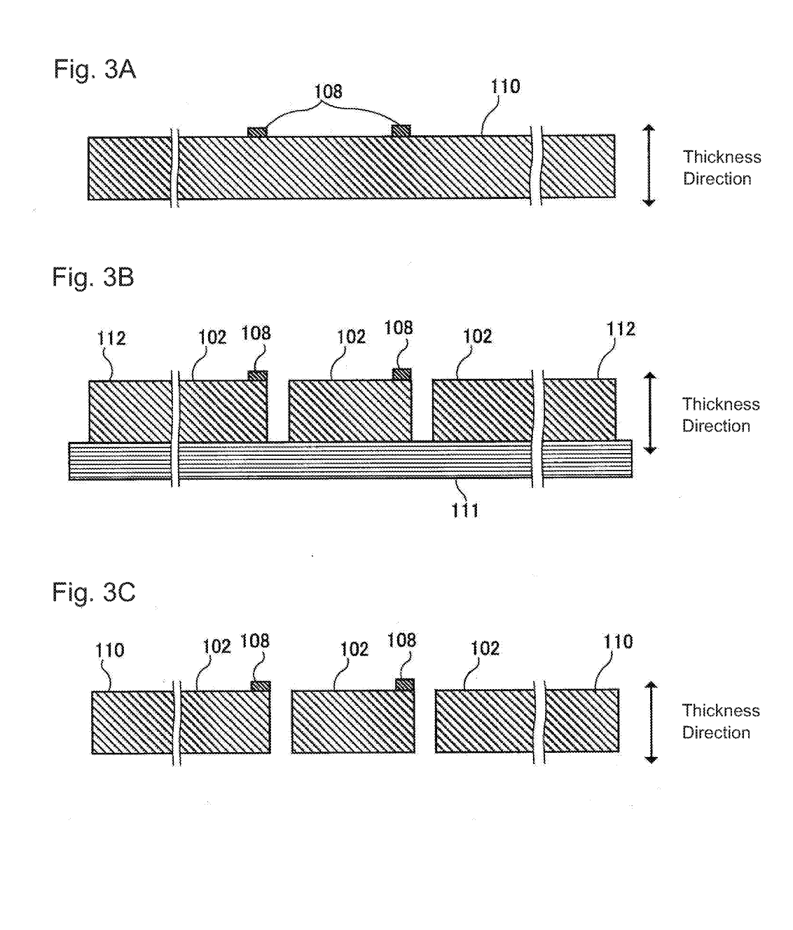

FIGS. 3A to 3C are cross-sectional views illustrating manufacturing steps of first semiconductor chip 102 of the semiconductor device according to the first embodiment. As illustrated in FIG. 3A, patterns of insulation members 108 are first formed on wafer 110. This step is also referred to as an insulation member pattern forming step. FIG. 3A illustrates a state in which the patterns of insulation members 108 are formed on wafer 110. A method of manufacturing a semiconductor chip generally includes a circuit pattern forming step which is a step of forming circuit patterns when the semiconductor chip is still in the state of wafer 110. The insulation member pattern forming step can be executed in the course of the circuit pattern forming step, and an execution timing thereof is not limited to a particular timing. Meanwhile, a method which implements the insulation member pattern forming step includes: a method of coating an insulative substance on wafer 110 and forming a pattern by etching the coated insulative substance; a method of coating a mixture of an insulative substance and a photosensitive material such as diazonaphthoquinone onto wafer 110, and forming a pattern of an insulation member by semiconductor photolithography; a screen printing method; a molding method; and the like. Note that the insulation member pattern forming step is not limited to the above-mentioned methods. In the meantime, each of a step of mounting a semiconductor chip on amount board and a step of resin-sealing a mount board inside a package generally involves a heating treatment. The heating treatment generally takes place in an atmosphere in a range from several tens of degrees Celsius to about 200° C. For this reason, insulation member 108 is preferably a substance that does not undergo softening, glass transition, or a change in shape attributed to any of the above during the heating treatment.

Next, wafer 110 is cut into pieces, each in the size of a semiconductor chip. FIG. 3B illustrates the state in which wafer 110 is cut into the pieces each in the size of a semiconductor chip. In this step, wafer 110 is attached to sheet 111, such as a tape, and is cut in a thickness direction of wafer 110 in this state. Each semiconductor chip 102 on sheet 111 is provided with insulation member 108. In the meantime, an outer peripheral portion of cut wafer 110 generally forms imperfect portion 112 that does not include a circuit pattern as a semiconductor chip. The method of cutting wafer 110 includes: a method of abrading and scraping a top surface of wafer 110 with a solid rotary blade which is usually called a blade; a method of performing etching in a liquid, gas, or plasma atmosphere; a method of irradiating a top surface of a wafer with a laser and causing a portion of wafer 110 irradiated with the laser to evaporate or sublimate; a method of irradiating only a specific layer inside a wafer with a laser so as to alter qualities of the specific layer and then splitting the wafer by use of a physical impact; and the like. However, the method of cutting wafer 110 in the invention is not limited to these methods.

Lastly, the semiconductor chips are separated from sheet 111. FIG. 3C illustrates a state in which semiconductor chips 102 are separated from sheet 111. As illustrated in FIG. 3C, semiconductor chips 102 are produced after removing sheet 111.

In FIG. 2, a distance between wire 107 and corner portion 102c of first semiconductor chip 102 is reduced due to a deformation of wire 107 caused by resin 116. However, corner portion 102c of first semiconductor chip 102 is covered with insulation member 108. Accordingly, wire 107 is prevented from coming into contact with first semiconductor chip 102.

As described above, in the first embodiment, insulation member 108 is provided on first upper surface 102u of first semiconductor chip 102 and is located closer to second electrode pad 105 than first electrode pad 104 is. Thus, corner portion 102c of first semiconductor chip 102 is covered with insulation member 108, and any exposure of corner portion 102c of first semiconductor chip 102 is suppressed. For this reason, if a wire displacement occurs in the course of filling the package with the resin, it is possible to reduce a risk of contact between wire 107 and first semiconductor chip 102, and thus to prevent the occurrence of a short circuit between wire 107 and first semiconductor chip 102.

Moreover, since the height of the wire from the surface of the semiconductor chip does not have to be increased, it is also possible to avoid contact between adjacent wires due to a wire displacement.

Furthermore, since no additional steps such as a step of forming a bump on a pad are required, it is also possible to reduce the manufacturing cost of the semiconductor device.

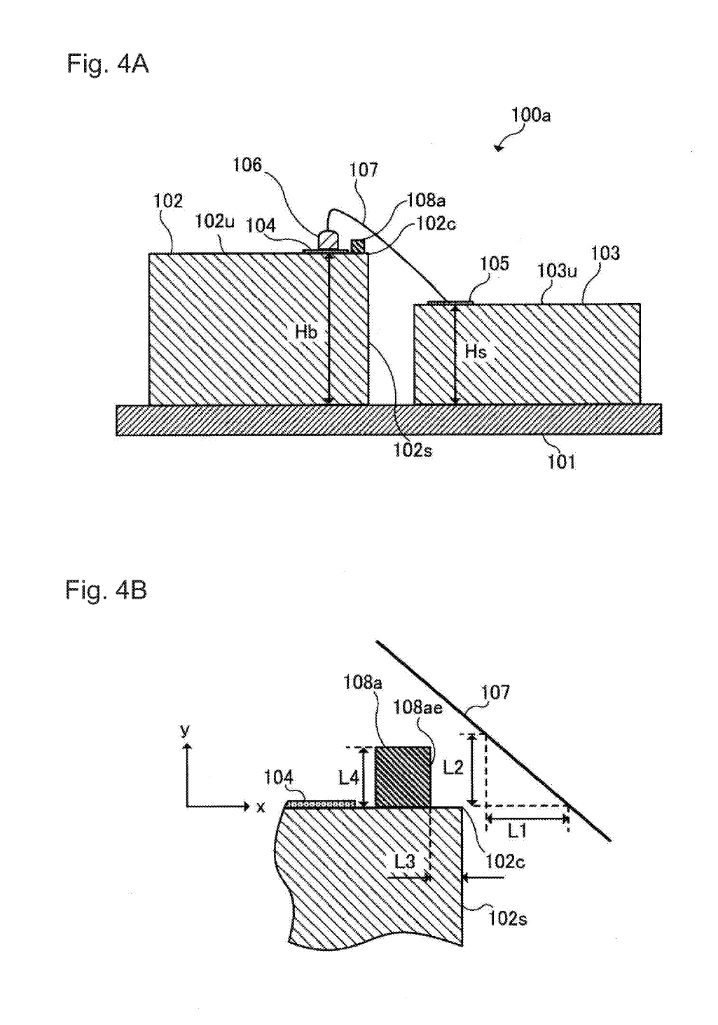

FIG. 4A is a cross-sectional view schematically illustrating a configuration of a semiconductor device according to a first modified example of the first embodiment, and FIG. 4B is an enlarged cross-sectional view illustrating a substantial part of the semiconductor device in FIG. 4A. In FIGS. 4A and 4B, constituents that are identical or corresponding to those in FIGS. 1A and 1B are denoted by the same reference numerals as the reference numerals in FIGS. 1A and 1B. In FIGS. 1A and 1B, end portion 108e of insulation member 108 on the second semiconductor chip 103 side is disposed in such a way as to overlap corner portion 102c as the end portion of upper surface 102u of first semiconductor chip 102 on the second semiconductor chip 103 side. In contrast, in the first modified example illustrated in FIGS. 4A and 4B, end portion 108ae of insulation member 108a on the second semiconductor chip 103 side is disposed in such a way as to be located between first electrode pad 104 and corner portion 102c as the end portion of first semiconductor chip 102 on the second semiconductor chip 103 side as illustrated in FIGS. 4A and 4B. As illustrated in FIG. 4B, end portion 108ae of insulation member 108a on the second semiconductor chip 103 side is disposed inward from corner portion 102c of upper surface 102u of first semiconductor chip 102 on the second semiconductor chip 103 side. In other words, end portion 108ae of insulation member 108a on the second semiconductor chip 103 side is disposed in such a way as to be located closer to first electrode pad 104 than is corner portion 102c of upper surface 102u of first semiconductor chip 102 on the second semiconductor chip 103 side in the x-axis direction. In order not to cause wire 107 to come into contact with first semiconductor chip 102 in the first modified example, the height of insulation member 108a from upper surface 102u of first semiconductor chip 102 needs to be formed substantially large. In this case, it is preferable that lengths L1, L2, L3, and L4 indicated in FIG. 4B satisfy the relation of (L4/L3)>(L2/L1). Here, a length L is in a range from several micrometers to several tens of micrometers. Note that the method of manufacturing the first semiconductor chip in the first modified example is similar to that in the case of the first embodiment illustrated in FIGS. 3A to 3C.

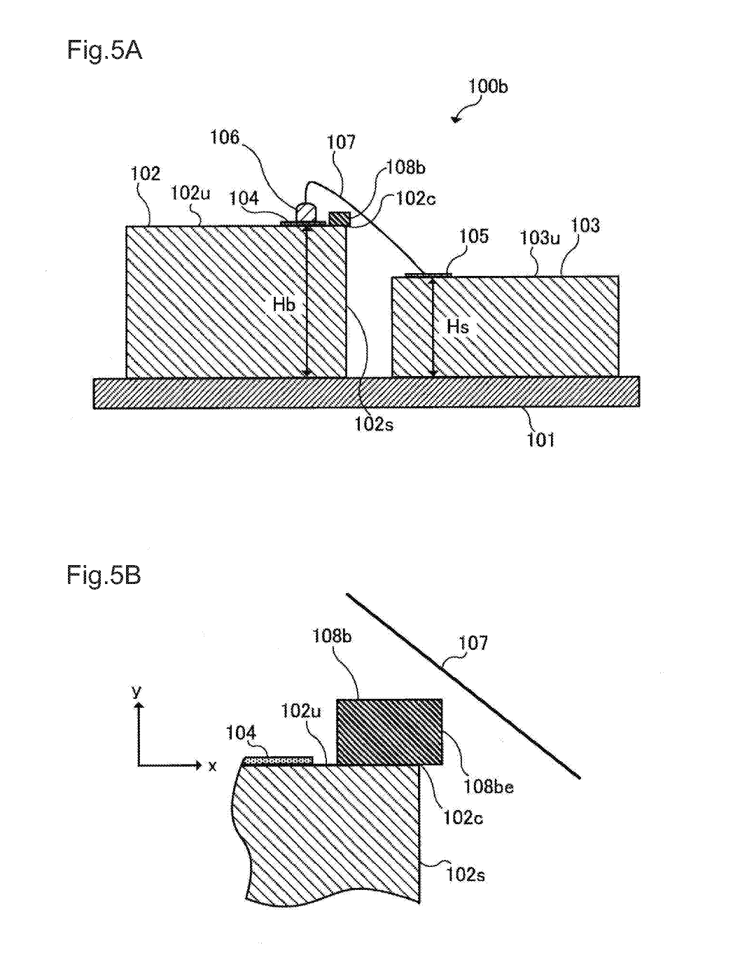

FIG. 5A is a cross-sectional view schematically illustrating a configuration of a semiconductor device according to a second modified example of the first embodiment, and FIG. 5B is an enlarged cross-sectional view illustrating a substantial part of the semiconductor device in FIG. 5A. In FIGS. 5A and 5B, constituents that are identical or corresponding to those in FIGS. 1A and 1B are denoted by the same reference numerals as the reference numerals in FIGS. 1A and 1B. In the second modified example, end portion 108be of insulation member 108b on the second semiconductor chip 103 side is disposed in such a way as to protrude outward from corner portion 102c as the end portion of upper surface 102u of first semiconductor chip 102 on the second semiconductor chip 103 side. In other words, end portion 108be of insulation member 108b on the second semiconductor chip 103 side is disposed in such a way as to be located closer to second semiconductor chip 103 than is corner portion 102c of upper surface 102u of first semiconductor chip 102 on the second semiconductor chip 103 side in the x-axis direction.

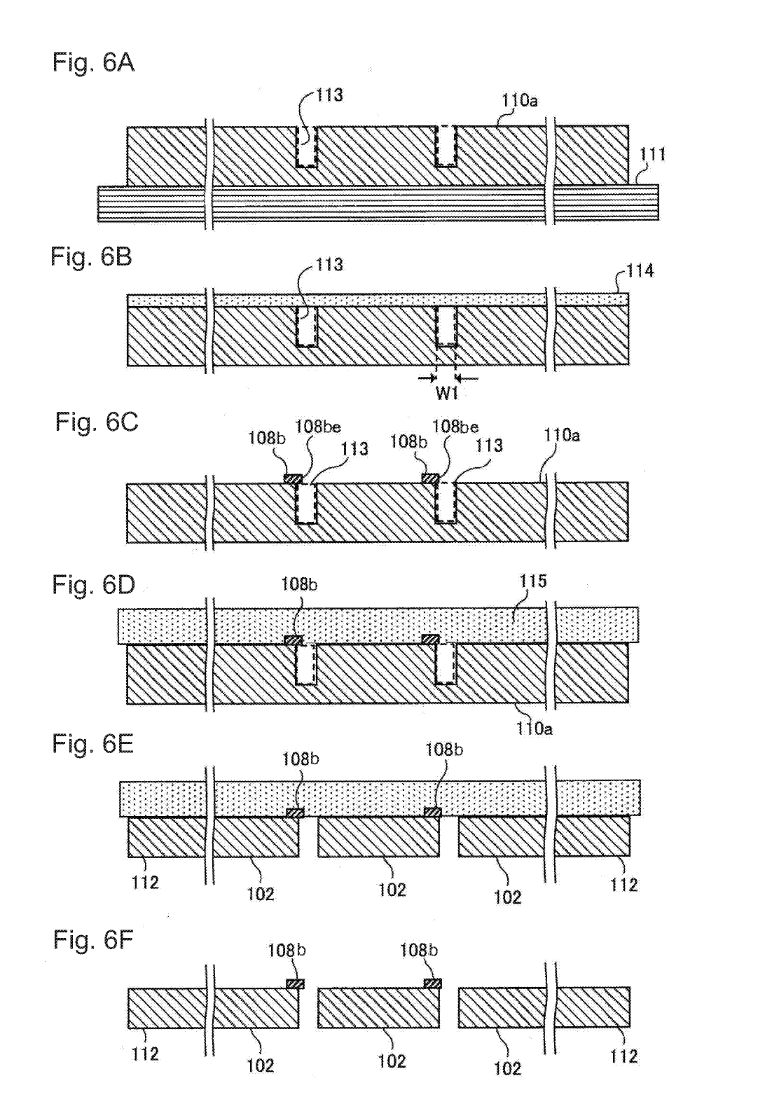

FIGS. 6A to 6F are views illustrating manufacturing steps of the first semiconductor chip of the second modified example of the first embodiment. FIGS. 6A to 6F illustrate schematic cross-sectional views of wafer 110a. While the following description explains the case of the second modified example of the first embodiment illustrated in FIGS. 5A and 5B, this description is also applicable to the case of the first embodiment illustrated in FIGS. 1A and 1B and the case of the first modified example of the first embodiment illustrated in FIGS. 4A and 4B. In the following description, features different from those in the manufacturing method of the first embodiment are explained while omitting explanation of the same features as those in the manufacturing method of the first embodiment.

First, grooves 113 are formed in the top surface of wafer 110a. FIG. 6A illustrates a state in which grooves 113 are formed in wafer 110a. The step of forming the grooves is performed after the circuit pattern forming step and usually in a state where wafer 110a is attached to sheet 111, such as a tape. The method of forming grooves 113 includes: a method of abrading and scraping the top surface of wafer 110a with a solid rotary blade which is called a blade; a method of performing etching in a liquid, gas, or plasma atmosphere; a method of irradiating the top surface of wafer 110a with a laser and causing a portion of wafer 110a to evaporate or sublimate; and the like. However, the method of forming grooves 113 in the invention is not limited to these methods.

Next, film 114 made of the insulative material constituting the material of insulation member 108b is attached to the top surface of wafer 110a. FIG. 6B illustrates a state in which film 114 is attached to the top surface of wafer 110a. Here, a width W1 of each groove 113 preferably has such a width that does not cause attached film 114 to fall into groove 113. When film 114 has a thickness of several tens of micrometers or above, film 114 can be attached without falling into groove 113 by setting the width W1 of each groove 113 equal to or below about 100 μm. Note that a relation between the thickness of film 114 and the width W1 of groove 113 is not limited to the above case.

Next, film 114 is processed to form patterns of insulation members 108b. FIG. 6C illustrates a state in which the patterns of insulation members 108b are formed on wafer 110a. The method of implementing this insulation member pattern forming step is the same as the insulation member pattern forming step in the manufacturing method of the first embodiment, and its description is therefore omitted. Here, when end portion 108be of each insulation member is formed at a position above groove 113 (i.e., a position protruding outward from upper surface 102u of semiconductor chip 102) as illustrated in FIG. 6C, the method of implementing the insulation member pattern forming step preferably adopts any of a method of forming patterns by etching film 114, and a method of mixing a photosensitive material such as diazonaphthoquinone with film 114 and forming the patterns by semiconductor photolithography. As for the material of insulation member 108b, it is desirable to employ a material having the property of being hardened in a chemical treatment or a heating treatment in the process of forming the insulation member 108b.

Next, as illustrated in FIG. 6D, sheet 115 such as a tape is attached to the top surface of wafer 110a. Then, the thickness of wafer 110a is reduced from a bottom surface of wafer 110a. FIG. 6E illustrates a state in which wafer 110a is split into semiconductor chips 102 as a consequence of the above-mentioned step. The method of reducing the thickness of wafer 110a includes an abrading method, a method of performing etching in a liquid, gas, or plasma atmosphere, and the like. However, the method of reducing the thickness of wafer 110a in the invention is not limited to these methods. Lastly, semiconductor chips 102 are separated by removing sheet 115 as illustrated in FIG. 6F.

As described above, according to the semiconductor device of the first embodiment, the insulation member, which is provided on the upper surface of the first semiconductor chip and is located at the position closer to the second electrode pad than the first electrode pad is, can prevent the occurrence of a short circuit between the corner portion of the first semiconductor chip and the wire even when the wire has a small height from the upper surface of the first semiconductor chip.

Moreover, according to the semiconductor device of the first embodiment, the upper surface of the second semiconductor chip is located lower than the upper surface of the first semiconductor chip. As a consequence, it is possible to reduce the chance of the occurrence of a short circuit between the second semiconductor chip and the wire even when the wire has a small height from the upper surface of the first semiconductor chip.

Furthermore, according to the semiconductor device of the first embodiment, the height of the wire from the upper surface of the first semiconductor chip can be reduced. Thus, it is possible to reduce the chance of the occurrence of a short circuit between adjacent wires.

### Second Embodiment

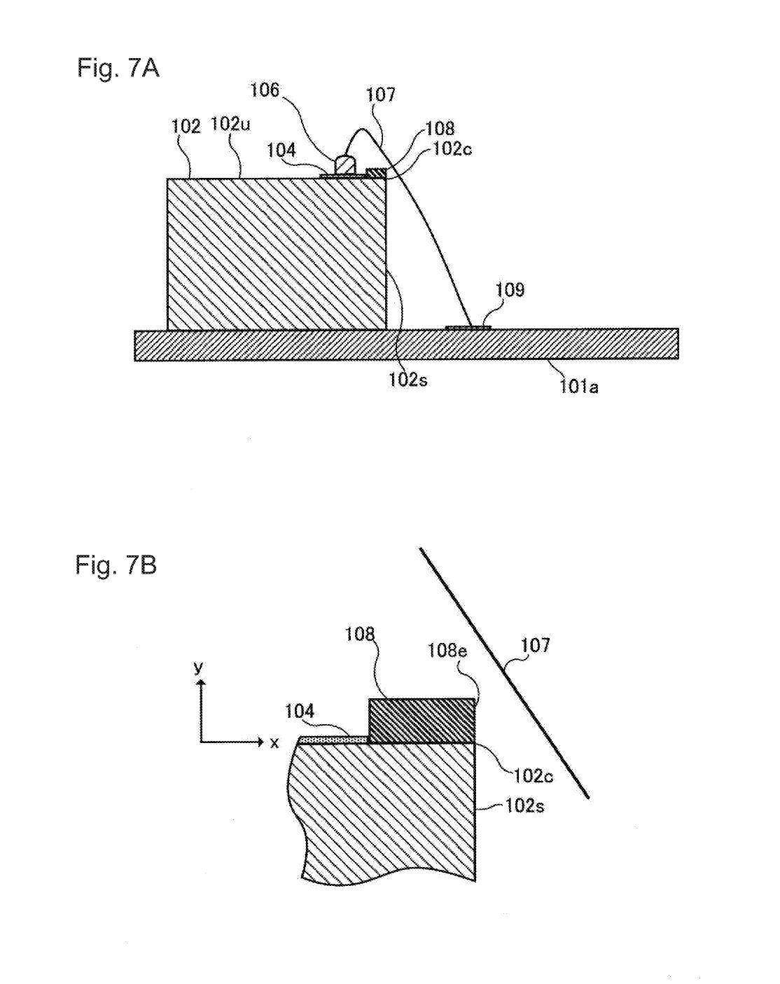

FIG. 7A is a cross-sectional view schematically illustrating the configuration of a semiconductor device according to a second embodiment of the invention, and FIG. 7B is an enlarged cross-sectional view illustrating a substantial part of the semiconductor device in FIG. 7A. In FIGS. 7A and 7B, constituents that are identical or corresponding to those in FIGS. 1A and 1B are denoted by the same reference numerals as the reference numerals in FIGS. 1A and 1B. The second embodiment is different from the first embodiment in that the circuit component in the first embodiment is the second semiconductor chip whereas the circuit component in the second embodiment is the mount board. In the following description, any explanation that is the same as the explanation in the first embodiment is omitted.

In FIG. 7A, first semiconductor chip 102 is disposed (horizontally placed) on mount board 101a. First semiconductor chip 102 includes first electrode pad 104 and insulation member 108 which are located on upper surface 102u. Moreover, mount board 101a includes pad 109 serving as an electrode pad. When first electrode pad 104 is connected to pad 109 with wire 107, ball bond 106 is formed on first electrode pad 104 while a stitch bond is formed on pad 109. In other words, wire 107 is fixed onto first electrode pad 104 by ball bond 106 and is fixed onto pad 109 by the stitch bond. Thus, first semiconductor chip 102 is electrically connected to mount board 101a. As illustrated in FIGS. 7A and 7B, end portion 108e of insulation member 108 on the pad 109 side is disposed in such a way as to overlap corner portion 102c as the end portion of first semiconductor chip 102 on the pad 109 side. As illustrated in FIG. 7B, respective end portions of insulation member 108 and first semiconductor chip 102 on the pad 109 side are disposed in alignment with each other in the x-axis direction. In other words, end portion 108e of insulation member 108 on the pad 109 side and corner portion 102c as the end portion of upper surface 102u of first semiconductor chip 102 on the pad 109 side are disposed so as to be aligned at the same position in the x-axis direction.

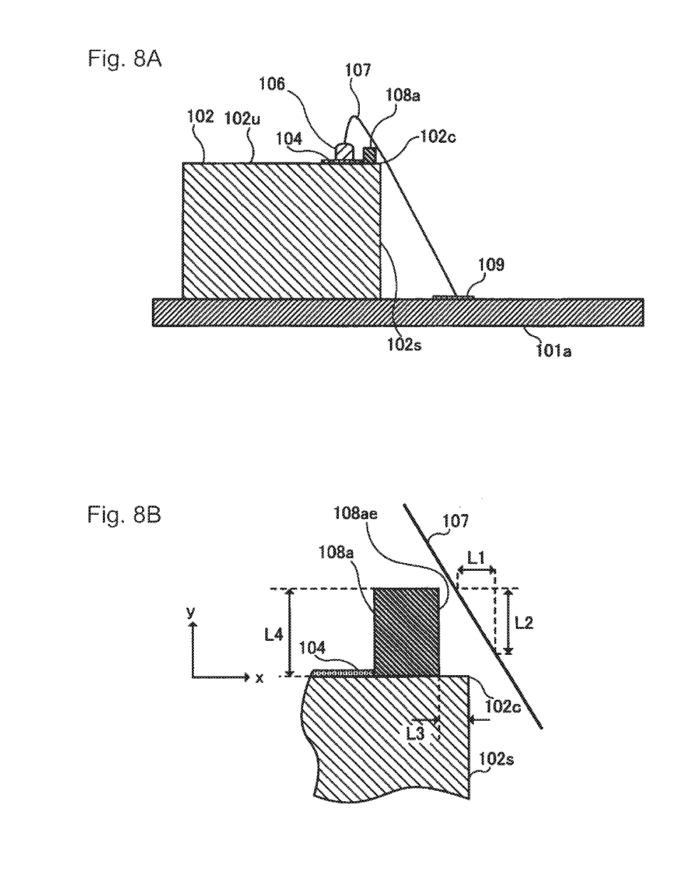

FIG. 8A is a cross-sectional view schematically illustrating the configuration of a semiconductor device according to a first modified example of the second embodiment, and FIG. 8B is an enlarged cross-sectional view illustrating a substantial part of the semiconductor device in FIG. 8A. In FIGS. 8A and 8B, constituents that are identical or corresponding to those in FIGS. 7A and 7B are denoted by the same reference numerals as the reference numerals in FIGS. 7A and 7B. As illustrated in FIGS. 8A and 8B, end portion 108ae of insulation member 108a on the pad 109 side is disposed in such a way as to be located between first electrode pad 104 and corner portion 102c as the end portion of first semiconductor chip 102 on the pad 109 side. As illustrated in FIG. 8B, end portion 108ae of insulation member 108a on the pad 109 side is disposed inward from corner portion 102c of upper surface 102u of first semiconductor chip 102 on the pad 109 side. In other words, end portion 108ae of insulation member 108a on the pad 109 side is disposed in such a way as to be located closer to first electrode pad 104 than is corner portion 102c of upper surface 102u of first semiconductor chip 102 on the pad 109 side in the x-axis direction. In order not to cause first semiconductor chip 102 to come into contact with wire 107 in the first modified example, the height of insulation member 108a from upper surface 102u of semiconductor chip 102 needs to be formed substantially large. In this case, lengths L1, L2, L3, and L4 indicated in FIG. 8B only need to satisfy a relation of (L4/L3)>(L2/L1).

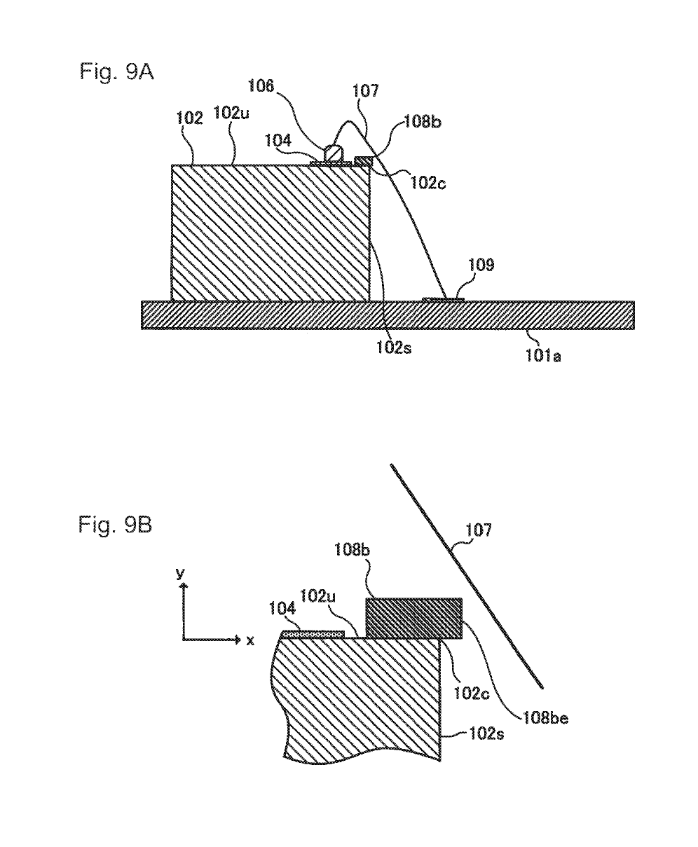

FIG. 9A is a cross-sectional view schematically illustrating the configuration of a semiconductor device according to a second modified example of the second embodiment, and FIG. 9B is an enlarged cross-sectional view illustrating a substantial part of the semiconductor device in FIG. 9A. In FIGS. 9A and 9B, constituents that are identical or corresponding to those in FIGS. 7A and 7B are denoted by the same reference numerals as the reference numerals in FIGS. 7A and 7B. In the second modified example, end portion 108be of insulation member 108b on the pad 109 side is disposed in such a way as to protrude outward from corner portion 102c as the end portion of upper surface 102u of first semiconductor chip 102 on the pad 109 side. In other words, end portion 108be of insulation member 108b on the pad 109 side is disposed in such a way as to be located closer to pad 109 than is corner portion 102c of upper surface 102u of first semiconductor chip 102 on the pad 109 side in the x-axis direction.

Note that the method of manufacturing insulation member 108b is the same as the manufacturing method of the first embodiment.

As described above, according to the semiconductor device of the second embodiment, the insulation member, which is provided on the upper surface of the first semiconductor chip and is located closer to the pad than the first electrode pad is, can prevent the occurrence of a short circuit between the corner portion of the first semiconductor chip and the wire even when the wire has a small height from the upper surface of the first semiconductor chip.

Moreover, according to the semiconductor device of the second embodiment, the height of the wire from the upper surface of the first semiconductor chip can be reduced. Thus, it is possible to reduce the chance of occurrence of a short circuit between adjacent wires.

### Third Embodiment

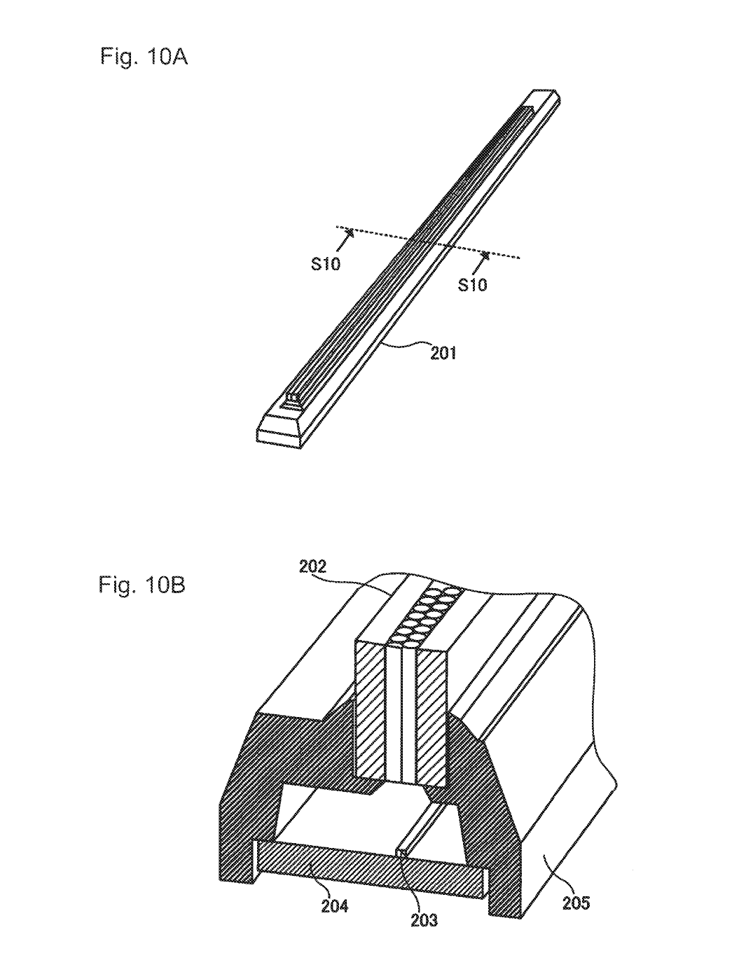

FIG. 10A is a perspective view schematically illustrating a configuration of an optical print head as a semiconductor device array according to a third embodiment of the invention, and FIG. 10B is an enlarged perspective view including a cross-section taken along an S10-S10 line in FIG. 10A. Optical print head 201 includes rod lens array 202, a mount board provided with chip 203 and printed wiring board 204, and frame 205. Rod lens array 202 is formed by arranging columnar lenses and integrating the lenses together. Chip 203 includes a semiconductor element array and an integrated circuit having a function to drive the semiconductor element array. Chip 203 is die-bonded onto printed wiring board 204. Frame 205 fixes rod lens array 202 and chip 203. Thus, optical print head 201 can focus light emitted from the semiconductor element array onto a photosensitive drum, for example. Here, aluminum, structural steel, or a resin can be employed as the material of frame 205. Meanwhile, the number of rows of lenses included in rod lens array 202 is not limited to two rows as illustrated in FIG. 10B.

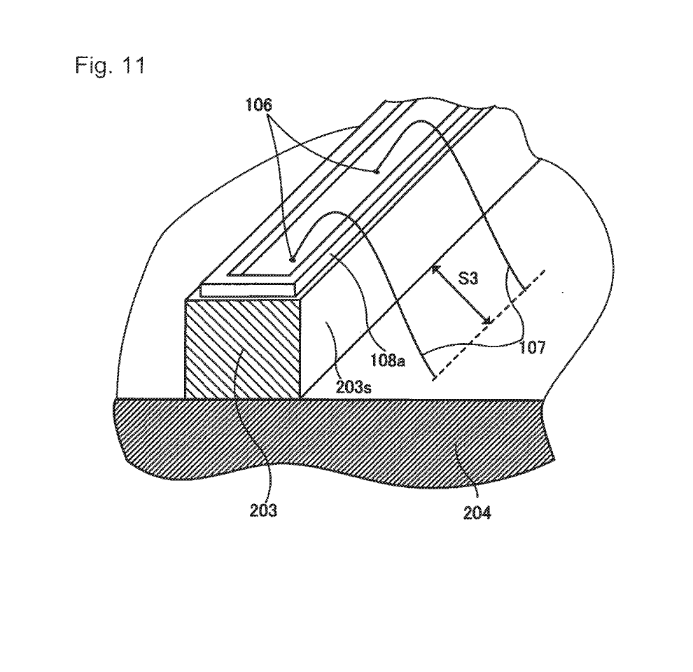

FIG. 11 is an enlarged perspective view illustrating a main part of optical print head 204 in FIG. 10A. FIG. 11 illustrates chip 203 and printed wiring board 204 as the mount board. In this embodiment, chip 203 is connected to printed wiring board 204 by using wire 107. The case illustrated in FIG. 11 corresponds to the case of the first modified example of the second embodiment. Here, insulation member 108a is formed between side surface 203s of chip 203 and a bonding pad (at a location where ball bond 106 is formed). Thus, even when the bonding pad on chip 203 and the bonding pad on printed wiring board 204 come close to each other and an interval S3 between the bonding pad on chip 203 and the bonding pad on printed wiring board 204 is reduced, it is possible to reduce the risk of contact between wire 107 and chip 203, and thus to prevent the occurrence of a short circuit between wire 107 and chip 203.

Here, the semiconductor device array illustrated in FIG. 11 may be a light-receiving element array that is provided with light-receiving elements instead of light-emitting elements, thereby constituting an optical reading unit (an image reading head) of an image reading apparatus.

### Fourth Embodiment

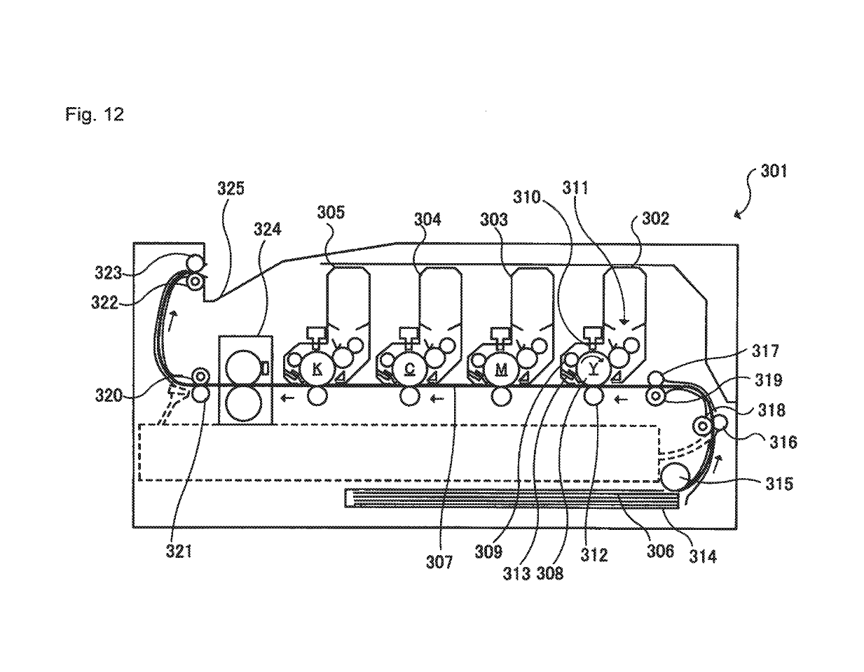

FIG. 12 is a vertical cross-sectional view schematically illustrating a configuration of an image formation apparatus according to a fourth embodiment of the invention. FIG. 12 illustrates LED printer 301 as the image formation apparatus that applies the optical print head according to the third embodiment. LED printer 301 includes four process units 302 to 305 configured to form images in colors of yellow (Y), magenta (M), cyan (C), and black (K) by using electrophotography. The optical print head of the third embodiment is applied to an exposure device in each of process units 302 to 305.

The process units are described to begin with. Process unit 302 includes: photoconductor drum 308 serving as an image carrier; charging device 309 disposed around photoconductor drum 308 and configured to charge a surface of photoconductor drum 308; and exposure device 310 which selectively irradiates the surface of charged photoconductor drum 308 with light and thus forms an electrostatic latent image. In addition, process unit 302 includes: development device 311 which conveys toner onto the surface of photoconductor drum 308 on which the electrostatic latent image is formed; and transfer roller 312 opposed to photoconductor drum 308. Here, photoconductor drum 308 is rotated in a direction indicated with an arrow by a driving mechanism formed from a driving source, gears, and the like. Meanwhile, transfer roller 312 is made of a semiconductive rubber and the like. An electric potential of photoconductor drum 308 and an electric potential of transfer roller 312 are set such that the toner image on photoconductor drum 308 can be transferred onto recording medium 306. Furthermore, process unit 302 includes cleaning device 313 that removes the toner remaining on the surface of photoconductor drum 308. Each of process units 303 to 305 has the same configuration as that of process unit 302. In LED printer 301, process units 302 to 305 are disposed in tandem (arranged in an upright manner) along conveyance path 307 for recording media 306.

Next, a configuration of LED printer 301 is described. LED printer 301 includes sheet cassette 314 that houses recording media 306 such as paper, and hopping roller 315 for separating and conveying recording media 306 one by one. Pinch rollers 316 and 317 and registration rollers 318 and 319 pinch recording media 306 and convey recording media 306 to process units 302 to 305, while correcting any oblique motion of recording media 306 with pinch rollers 316 and 317. Hopping roller 315 and registration rollers 318 and 319 are rotated by driving sources. Moreover, the image formation apparatus includes delivery rollers 320, 321, 322, and 323 for delivering recording media 306.

An operation of LED printer 301 is described. First, recording media 306 loaded on sheet cassette 314 are separated and conveyed one by one by using hopping roller 315. Each recording medium 306 is conveyed by pinch rollers 316 and 317 and registration rollers 318 and 319, and passes sequentially through process units 302 to 305. In each of process units 302 to 305, recording medium 306 passes through between the photoconductor drum and the transfer roller, whereby toner images in the respective colors are sequentially transferred thereto. The toner images are heated and pressurized by fusing device 324 and are thus fused onto recording medium 306. Thereafter, recording medium 306 is delivered onto stacker 325 by delivery rollers 320, 321, 322, and 323.

The invention is not limited to the above-described embodiments. The invention can be modified without departing from the gist of the invention. The above-described embodiments merely represent certain examples to which the invention is applied. In this context, the invention is also applicable to devices and apparatuses other than a semiconductor device array and an image formation apparatus.

The invention includes other embodiments in addition to the above-described embodiments without departing from the spirit of the invention. The embodiments are to be considered in all respects as illustrative, and not restrictive. The scope of the invention is indicated by the appended claims rather than by the foregoing description. Hence, all configurations including the meaning and range within equivalent arrangements of the claims are intended to be embraced in the invention.

1. A semiconductor device comprising:
a first semiconductor chip including a first upper surface and a first electrode pad provided on the first upper surface;
a circuit component including a second upper surface disposed at a position lower than the first upper surface and a second electrode pad provided on the second upper surface, the circuit component being juxtaposed to the first semiconductor chip;
an insulation member provided on the first upper surface and located closer to the second electrode pad than the first electrode pad is; and
a wire extending from the first electrode pad to the second electrode pad while passing above the insulation member.

2. The semiconductor device according to claim 1, wherein an end portion of the insulation member on the side of the circuit component overlaps an end portion of the first upper surface on the side of circuit component.

3. The semiconductor device according to claim 1, wherein an end portion of the insulation member on the side of circuit component is located between an end portion of the first upper surface on the side of the circuit component and the first electrode pad.

4. The semiconductor device according to claim 1, wherein an end portion of the insulation member on the side of the circuit component protrudes outward from an end portion of the first upper surface on the side of the circuit component.

5. The semiconductor device according to claim 1, wherein the wire is a bonding wire that electrically connects the first electrode pad to the second electrode pad.

6. The semiconductor device according to claim 5, wherein
the wire is fixed onto the first electrode pad by a ball bond, and is fixed onto the second electrode pad by a stitch bond.

7. The semiconductor device according to claim 1, wherein the circuit component comprises a second semiconductor chip.

8. The semiconductor device according to claim 1, further comprising:
a mount board, wherein
the first semiconductor chip and the circuit component are disposed on the mount board.

9. The semiconductor device according to claim 1, wherein
the circuit component comprises a mount board, and
the first semiconductor chip is disposed on the second upper surface of the mount board.

10. The semiconductor device according to claim 1, wherein the insulation member is made of at least one material out of epoxy resin, polyimide, acrylic resin, and phenol resin.

11. The semiconductor device according to claim 8, wherein the mount board is any one of a glass epoxy board and a ceramic board.

12. The semiconductor device according to claim 8, wherein the mount board is any one of a polyimide board and a polyester board.

13. A semiconductor device array comprising:
a semiconductor chip including semiconductor elements, wherein
the semiconductor chip is the first semiconductor chip of the semiconductor device according to claim 1.

14. The semiconductor device array according to claim 13, wherein the semiconductor elements are light-emitting elements.

15. The semiconductor device array according to claim 13, wherein the semiconductor elements are light-receiving elements.

16. An image formation apparatus comprising the semiconductor device array according to claim 14 as an optical print head.
